(19) United States
(12) Patent Application Publication
(10) Pub. No.: US 2021/0062324 A1
(43) Pub. Date: Mar. 4, 2021

(54) ELECTRON BEAM PVD ENDPOINT DETECTION AND CLOSED-LOOP PROCESS CONTROL SYSTEMS

(71) Applicant: Applied Materials, Inc., Santa Clara, CA (US)

(72) Inventors: David Masayuki ISHIKAWA, Mountain View, CA (US); Jonathan FRANKEL, Los Gatos, CA (US); Joseph YUDOVSKY, Campbell, CA (US); David Alexander BRITZ, San Jose, CA (US)

(21) Appl. No.: 16/995,662

(22) Filed: Aug. 17, 2020

Related U.S. Application Data
(60) Provisional application No. 62/894,304, filed on Aug. 30, 2019.
(60) Provisional application No. 62/894,209, filed on Aug. 30, 2019.

(51) Int. Cl. C23C 14/30; C23C 14/54; C23C 14/52; H01J 37/305

(52) U.S. Cl. CPC C23C 14/30; C23C 14/545; H01J 2237/24585; H01J 37/3053; H01J 2237/30466; C23C 14/52

(57) ABSTRACT

Embodiments described herein provide apparatus, software applications, and methods of a coating process, such as an Electron Beam Physical Vapor Deposition (EBPVD) of thermal barrier coatings (TBCs) on objects. The objects may include aerospace components, e.g., turbine vanes and blades, fabricated from nickel and cobalt-based super alloys. The apparatus, software applications, and methods described herein provide at least one of the ability to detect an endpoint of the coating process, i.e., determine when a thickness of a coating satisfies a target value, and the ability for closed-loop control of process parameters.

### CROSS-REFERENCE TO RELATED APPLICATIONS

This application claims priority to U.S. Appl. No. 62/894,304, filed Aug. 30, 2019 and U.S. Appl. No. 62/894,209, filed Aug. 30, 2019, which are herein incorporated by reference.

### BACKGROUND

### Field

Embodiments presented herein generally relate to an application of a coating. More specifically, embodiments presented herein relate to apparatus and methods for determining an endpoint of a coating process.

### Description of the Related Art

Thermal barrier coatings (TBCs) protect metal substrates from high temperature oxidation and corrosion. Conventional techniques to apply TBCs to a metal substrate include Electron Beam Physical Vapor Deposition (EBPVD). Application of TBCs is typically controlled by an open loop control system which involves inadequate electron beam scanning and manual adjustment of process parameters. The open loop control results in low throughput and performance variability of the TBCs due to variation and nonconformance of TBC thickness and quality.

Further, to perform the conventional technique, a human operator applies a TBC to a workpiece and performs various measurements on the TBC. For example, the operator may remove the workpiece from the chamber and determine a weight of the workpiece with the coating applied. A difference between the weight of the workpiece with the coating and without the coating is used to determine a thickness of the coating. Based on those measurements, the operator adjusts parameters of the EBPVD process to obtain a more uniform TBC over an entire surface of the workpiece. However, the weight based thickness measurement provides no indication of coating uniformity. Moreover, this process is time consuming and results in less than optimal coating uniformity and quality.

Thickness and quality measurements performed by the operator results in variations in the TBCs. That is, the coating quality and thickness may be different depending on the subjective opinion of the operator regarding quality or coating time.

Thus, improved apparatus and processes for application of TBCs are needed.

### SUMMARY

In one embodiment, a method for detecting an endpoint of a coating process is provided. The method includes measuring a temperature of a plurality of substrates being processed. The method also includes comparing the measured temperature to a temperature threshold. The method also includes upon determining that the measured temperature does not satisfy the temperature threshold, adjusting a parameter of the coating process. The method also includes upon determining that the measured temperature satisfies the temperature threshold, measuring a thickness of a coating deposited on the plurality of substrates. The method also includes comparing the measured coating thickness to a target coating thickness. The method also includes upon determining that the measured coating thickness does not satisfy the target coating thickness, depositing an additional thickness of the coating on the plurality of substrates.

In another embodiment, a method of measuring a coating thickness is provided. The method includes aligning a test structure disposed on a probe between a first window and a second window. The method also includes measuring a first distance between a first laser source through the first window and a first surface of the test structure. The method also includes measuring a second distance between a second laser source through the second window and a second surface of the test structure. The method also includes extending the probe into a process chamber in which a coating is applied to a plurality of substrates and the test structure. The method also includes retracting the probe from the process chamber to align the test structure between the first window and the second window. The method also includes measuring a third distance between the first laser source and a surface of the coating deposited on the first surface of the test structure. The method also includes measuring a fourth distance between the second laser source and a surface of the coating deposited on the second surface of the test structure. The method also includes determining a first difference between the first distance and the third distance. The method also includes determining a second difference between the second distance and the fourth distance. The method also includes determining a thickness of the coating based on the first difference and the second difference. The method also includes comparing the thickness of the coating to a target coating thickness. The method also includes upon determining the thickness of the coating satisfies the target coating thickness, identifying an endpoint of a coating process performed on the plurality of substrates.

In yet another embodiment, a process chamber is provided. The process chamber includes a body defining a process volume therein. A melt pool is disposed in the process volume. One or more ingots are disposed in the melt pool. One or more electron beam generators are disposed opposite the melt pool. A plurality of substrates is disposed in the process volume between the one or more electron beam generators and the melt pool. A probe assembly of the process chamber includes an enclosure having a first window and a second window opposite the first window. The first window and the second window are adjacent to the body. A shaft is disposed in the enclosure. A test structure is disposed on the shaft. The process chamber also includes a controller configured to perform operations. The operations include aligning the test structure in the enclosure between the first window and the second window. The operations also include rotating each substrate of the plurality of substrates about more than one axis. The operations also include vaporizing the one or more ingots to generate a vapor plume surrounding the plurality of substrates by controlling a power provided to the one or more electron beam generators. The operations also include extending the test structure into the vapor plume. The operations also include retracting the test structure into the enclosure. The operations also include aligning the test structure between the first window and the second window. The operations also include determining a thickness of a coating deposited on the test structure. The operations also include upon determining that the thickness of the coating satisfies a target coating thickness, identifying an endpoint of a coating process for the plurality of substrates.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, as the disclosure may admit to other equally effective embodiments.

FIG. 1A is a schematic view of a partial system, such as an EBPVD system, according to some embodiments.

FIG. 1B is a schematic view of a system, such as an EBPVD system, according to some embodiments.

FIG. 1C is a schematic view of a workpiece holder, according to some embodiments.

FIG. 2 is a schematic view of a coating chamber, according to some embodiments.

FIG. 3 is a schematic view of a probe, according to some embodiments.

FIG. 4 is a schematic view of an alternative probe, according to some embodiments.

FIG. 5 is a schematic view of a coating chamber, according to some embodiments.

FIG. 6 is a schematic view of a coating chamber, according to some embodiments.

FIG. 7 is a flow chart depicting operations for monitoring a thickness of a coating deposited on a substrate, according to some embodiments.

FIG. 8 is a flow chart depicting operations for monitoring a thickness of a coating deposited on a substrate, according to some embodiments.

FIG. 9 is a flow chart depicting operations for monitoring various parameters of a coating procedure performed in a coating chamber, according to some embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein provide apparatus, software applications, and methods of a coating process, such as an Electron Beam Physical Vapor Deposition (EBPVD) of thermal barrier coatings (TBCs) on objects. The objects may include aerospace components, e.g., turbine vanes and blades, fabricated from nickel and cobalt-based super alloys. The apparatus, software applications, and methods described herein provide at least one of the ability to detect an endpoint of the coating process, i.e., determine when a thickness of a coating satisfies a target value, and the ability for closed-loop control of process parameters.

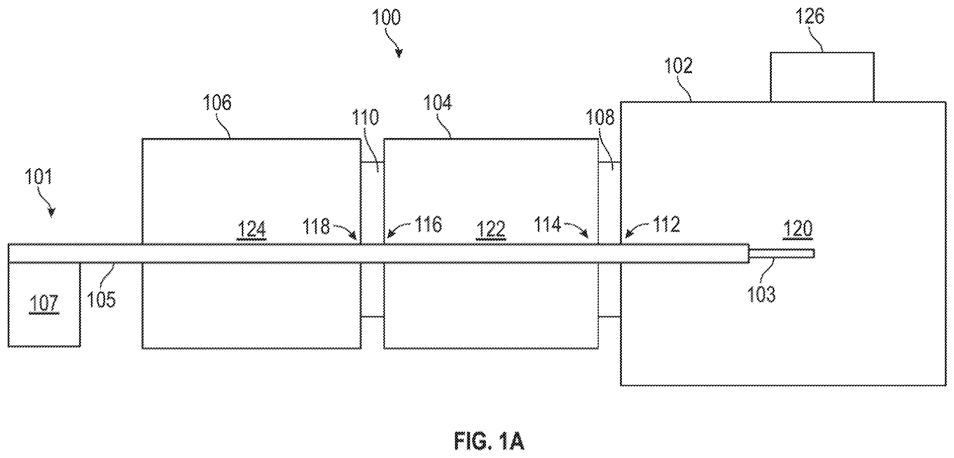

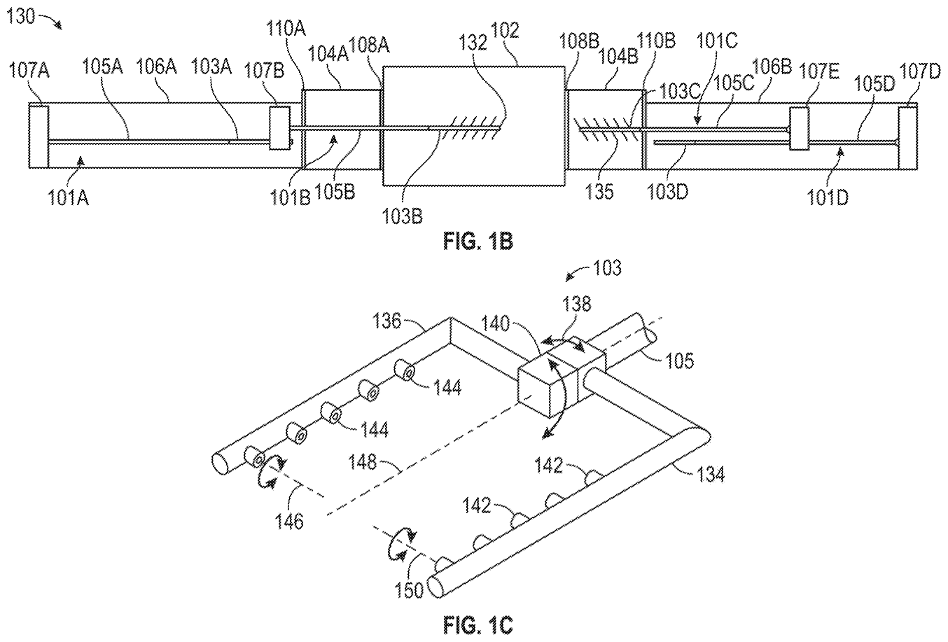

FIG. 1A is a schematic view of a system 100, such as an EBPVD system, that may benefit from embodiments described herein. It is to be understood that the system described below is an exemplary system and other systems, including systems from other manufacturers, may be used with or modified to accomplish aspects of the present disclosure. The system 100 includes a coating chamber 102 having a process volume 120, a preheat chamber 104 having an interior volume 122, and a loading chamber 106 having an interior volume 124. The preheat chamber 104 is positioned adjacent to the coating chamber 102 with a valve 108 disposed between an opening 112 of the preheat chamber 104 and an opening 114 of the preheat chamber 104. The loading chamber 106 is positioned adjacent to the preheat chamber 104 with a valve 110 disposed between an opening 116 of the preheat chamber 104 and an opening 118 of the loading chamber 106.

The system 100 further includes a carrier system 101. The carrier system 101 includes a holder 103 disposed on a shaft 105. The holder 103 is movably disposable in the interior volumes 120, 122, 124. The shaft 105 extends through the loading chamber 106, the preheat chamber 104, and the coating chamber 102. The shaft 105 is connected to a drive mechanism 107 that moves the holder 103 to one of a loading position (discussed with respect to FIG. 1B) in the loading chamber 106, a preheat position (discussed with respect to FIG. 1B) in the preheat chamber 104, and a coating position (as shown in FIG. 1A) in the coating chamber 102. The drive mechanism 107 is disposed adjacent to the loading chamber 106.

In one embodiment, the valves 108 and 110 are gate valves which seal the adjacent chambers 102, 104, and 106. An electron beam generator 126 is coupled to the coating chamber 102. The electron beam generator 126 provides sufficient energy to the process volume 120 to deposit a coating on a workpiece (not shown) disposed on the holder 103 within the process volume 120.

FIG. 1B is a schematic view of a system 130, such as an EBPVD system, according to some embodiments. The system 130 includes one or more carrier systems, such as a first carrier system 101A, a second carrier system 101B, a third carrier system 101C, and a fourth carrier system 101D. The system 130 includes a coating chamber 102 coupled to a first preheat chamber 104A and a second preheat chamber 104B. The second preheat chamber 104B is opposite the first preheat chamber 104A. A first loading chamber 106A is coupled to the first preheat chamber 104A opposite the coating chamber 102. A second loading chamber 106B is coupled to the second preheat chamber 104B opposite the coating chamber 102.

The first preheat chamber 104A is adjacent to the first loading chamber 106A and the coating chamber 102. The second preheat chamber 104B is adjacent to the second loading chamber 106B and the coating chamber 102. A valve 108A, 108B, 110A, and 110B is disposed between each of the adjacent chambers. The valves 108A and 108B correspond to the valve 108 described with respect to FIG. 1A. Similarly, the valves 110A and 110B correspond to the valve 110 described with respect to FIG. 1A. Each of the carrier systems 101A, 101B, 101C, and 101D includes a drive mechanism 107A, 107B, 107C, 107D, a shaft 105A, 105B, 105C, 105D, and a holder 103A, 103B, 103C, 103D, respectively.

As shown, the first carrier system 101A is in a loading (or unloading) position in which the first holder 103A is disposed within the first loading chamber 106A. The second carrier system 101B is in the processing position where the second holder 103B is disposed within the coating chamber 102. The third carrier system 101C is in the preheat position where the third holder 103C is disposed in the second preheat chamber 104B. A first plurality of substrates 132 are disposed on the second holder 103B and a second plurality of substrates 135 are disposed on the third holder 103C. The fourth carrier system 101D is in the unloading (or loading) position where the fourth holder 103D is disposed within the second loading chamber 106B.

Each of the one or more carrier systems 101A, 101B, 101C, and 101D is similar to the carrier system 101 described with respect to FIG. 1A. For example, the first carrier system 101A includes a first holder 103A disposed on a first shaft 105A. The first shaft 105A is coupled to a first drive mechanism 107A which move the first shaft and the first holder between the loading, the preheat, and the coating positions, as described above.

During operation, one or more substrates, such as the substrates 132, are positioned on each of the holders 103A, 103B, 103C, and 103D in the loading chambers 106A and 106B. The one or more substrates on each of the holders 103A, 103B, 103C, and 103D are asynchronously moved to the respective preheat chamber 104A and 104B and then moved to the coating chamber 102.

At a given time during processing, at least one of the holders 103A, 103B, 103C, and 103D is positioned in the coating chamber 102 and another holder is positioned in the respective preheat chamber 104A. For example, while the one or more substrates 132 on the second holder 103B are processing in the coating chamber 102, one or more additional substrates 135 on the third holder 103C are heated in the second preheat chamber 104B. Simultaneously, a third plurality of substrates (not shown) is loaded onto the first holder 103A in the first loading chamber 106A. A fourth plurality of substrates, which were previously processed in the coating chamber 102, are unloaded from the fourth holder 103D positioned in the second loading chamber 106B.

After processing of the one or more substrates 132 is completed, the processed substrates 132 are moved to the first loading chamber 106A to be cooled and unloaded from the second holder 103B. While the processed substrates 132 are unloaded, the one or more substrates on the first holder 103A are heated in the first preheat chamber 104A. Simultaneously, the one or more additional substrates 135 on the third holder 103C are processed in the coating chamber 102. Further, one or more substrates (not shown) may be loaded onto the fourth holder 103D in the second loading chamber 106B.

In one embodiment, which may be combined with one or more embodiments discussed above, a third loading chamber (not shown) may be positioned adjacent to the first loading chamber 106A. In that embodiment, the first carrier system 101A is moveably disposed between the coating chamber 102, the first preheat chamber 104A, and the first loading chamber 106A. The second carrier system 101B may be disposed in the third loading chamber. That is, the second carrier system 101B is moveably disposed between the coating chamber 102, the first preheat chamber 104A, and the third loading chamber.

The first loading chamber 106A and the third loading chamber may be moved in a direction substantially perpendicular to the first shaft 105A and the second shaft 105B such that either the first loading chamber 106A or the third loading chamber is coupled to the first preheat chamber 104A at a time.

Similarly, a fourth loading chamber (not shown) may be positioned adjacent to the second loading chamber 106B. The third carrier system 101C is moveably disposed between the coating chamber 102, the second preheat chamber 104B, and the second loading chamber 106B. The third carrier system 101C is moveably disposed between the coating chamber 102, the first preheat chamber 104A, and the fourth loading chamber.

The third loading chamber and the fourth loading chamber may be moved in a direction substantially perpendicular to the third shaft 105C and the fourth shaft 105D such that either the second loading chamber 106B or the fourth loading chamber is coupled to the second preheat chamber 104B at a time.

FIG. 1C is a schematic view of a holder 103, according to some embodiments. The holder 103 includes a first arm 134 and a second arm 136. The first arm 134 is coupled to the shaft 105 via a first connector 138. The second arm 136 is coupled to the shaft 105 via a second connector 140. The first connector 138 and the second connector 140 are rotatably coupled to the shaft 105 and rotate about a central axis 148 of the shaft 105. In some embodiments, the first connector 138 and the second connector 140 are rigidly attached to the shaft 105.

One or more first standoffs 142 are attached to the first arm 134. One or more second standoffs 144 are attached to the second arm 136. The first standoffs 142 and the second standoffs 144 extend laterally from the first arm 134 and the second arm 136, respectively. The second standoffs 144 are substantially parallel to the first standoffs 142.

Each of the first standoffs 142 rotates about central axis 150 of that first standoff 142. Similarly, each of the second standoffs 144 rotates about a central axis 146 of that second standoff 144. The central axes 150 and 146 of the first standoffs 142 and the second standoffs 144, respectively, are substantially perpendicular to the central axis 148 of the shaft 105. In operation, one of more substrates (not shown) may be attached to the first standoffs 142 and the second standoffs 144 while positioned in a loading chamber, such as the first loading chamber 106A and the second loading chamber 106B discussed with respect to FIG. 1B.

In some embodiments, which can be combined with one or more embodiments discussed above, the shaft 105 is stationary and the first arm 134 and second arm 136 rotates about the central axis 148 of the shaft 105. In that embodiment, the first arm 134 and the second arm 136 are at an equivalent angle relative to the central axis of the shaft 105. For example, each of the first arm 134 and the second arm 136 rotates about the central axis 148 up to a maximum of about 90 degrees.

A controller (not shown) may be coupled to the holder 103 to control a speed of rotation of the one or more substrates positioned thereon. The controller may monitor and adjust a speed of rotation of the shaft 105 and the movement of the first arm 134 and the second arm 136. The controller may also monitor and adjust a speed of rotation for each of the standoffs 142, 144.

Adjusting a speed of rotation of the shaft 105, the first arm 134, the second arm 136, and the standoffs 142, 144 also adjust a speed of rotation of the substrates disposed thereon. Adjusting the speed of rotation of the one or more substrates reduces an occurrence of overheating of the substrates which results in damage to the substrates.

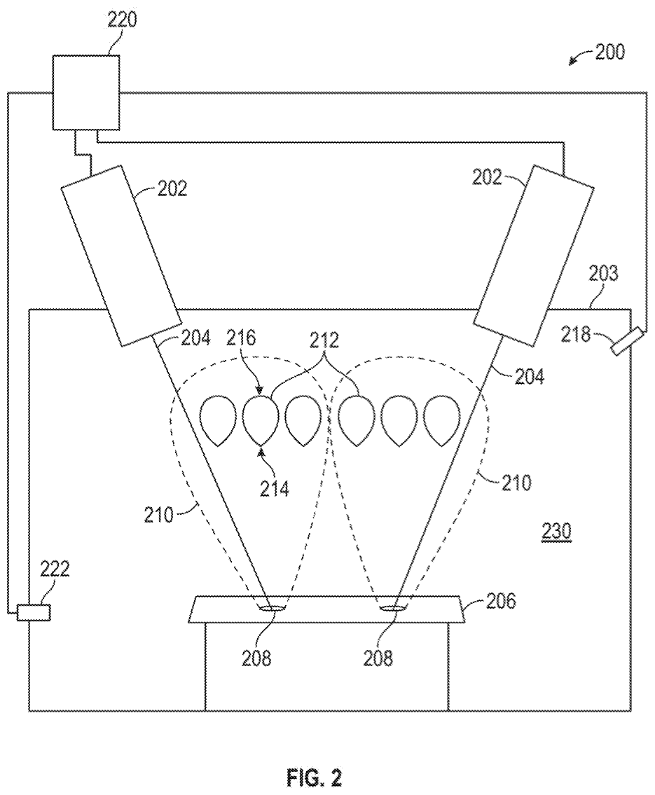

FIG. 2 is a schematic view of a coating chamber 200, according to some embodiments. The coating chamber 200 may correspond to the coating chamber 102 discussed with respect to FIGS. 1A and 1B. The coating chamber 200 includes a body 203 defining a process volume 230 therein. A melt pool 206 is disposed in the process volume 230. The melt pool 206 includes one or more ingots 208 fabricated from a ceramic containing material. One or more monitoring devices are disposed on the coating chamber 200. The monitoring devices include a pyrometer 218 and an infrared imaging device 222.

The coating chamber 200 includes one or more electron beam generators 202 disposed through the body 203. One or more substrates 212 are positioned in the process volume 230 between the one or more electron beam generators 202 and the melt pool 206. The one or more substrates 212 are disposed on a holder, such as the holder 103 described with respect to FIGS. 1A, 1B, and 1C.

During operation, the electron beam generators 202 generate an electron beam 204 directed at the one or more ingots 208. The electron beams 204 melt the material of the ingots 208 and create a vapor plume 210 between the melt pool 206 and the one or more electron beam generators 202 for each ingot 208. A coating is deposited on the one or more substrates 212 via the vapor of the vapor plumes 210.

The pyrometer 218 is disposed through the body 203. While one pyrometer 218 is shown, any number of pyrometers may be used. The pyrometer 218 may be a dual wavelength pyrometer. As shown, the pyrometer 218 extends through the body 203. However, the pyrometer 218 may be positioned in the process volume 230 or outside of the body 203.

The pyrometer 218 may be used to measure a temperature in the process volume 230 via a sight window (not shown) formed in the body 203. The pyrometer 218 may monitor a temperature of a chamber liner (not shown), the holder (such as the holder 103 described with respect to FIGS. 1A, 1B, and 1C), one or more of the substrates 212, and other components of the coating chamber 200. One or more additional pyrometers (not shown) may be disposed in a loading chamber, such as the loading chambers 106, 106A, and 106B discussed with respect to FIGS. 1A and 1B.

The infrared imaging device 222 is disposed through the body 203. In one embodiment, which can be combined with one or more embodiments discussed above, the infrared imaging device 222 may be a short wavelength infrared imaging device (SWIR). In one embodiment, which can be combined with one or more embodiments discussed above, the infrared imaging device 222 is disposed adjacent to the melt pool 206 to monitor a temperature of the melt pool 206 and detect boiling or eruptions of the melt pool 206. Eruptions of the melted ingot 208 material in the melt pool 206 may cause deviation of the vapor plume 210 resulting in a non-uniform coating deposited on the substrates 212.

The infrared imaging device 222 may be disposed in other locations in the process volume 230 or about the body 203. In some embodiments, one or more infrared imaging devices are disposed in a preheat chamber, such as the preheat chambers 104, 104A, and 104B described with respect to FIGS. 1A, 1B, and 1C. The infrared imaging device 222 may also be used to monitor a temperature of the chamber liners, the holder 103, the substrates 212, and other components of the coating chamber 200.

A controller 220 is coupled to the electron beam generators 202, the pyrometer 218, and the infrared imaging device 222. The controller 220 may also be coupled to the holder 103. In operation, the controller 220 receives signals from the monitoring devices 218, 222. Based on the signals, the controller 220 determines and adjusts a speed at which the substrates 212 are rotated on the standoffs 142, 144 and the shaft 105. The signals may indicate a temperature of the melt pool. The controller 220 can determine whether the melt pool 206 is overheated and adjust a temperature of the melt pool 206 by reducing a power of the respective electron beam generator 202.

While the pyrometer 218 and the infrared imaging device 222 are both illustrated in FIG. 2, each of the pyrometer 218 and the infrared imaging device 222 can be used individually with the coating chamber 200. Each of the pyrometer 218 and the infrared imaging device 222 enable improved coating capabilities of the coating process performed in the coating chamber 200. For example, a temperature or a coating rate of the substrates 212 may be used to determine a speed of rotation of the substrates 212. That is, the controller 220 may adjust a speed of rotation of the substrates 212 or the holder based on the measured data.

A first side 214 of the plurality of substrates 212 faces the melt pool 206. A second side 216 of the plurality of substrates 212 is opposite the first side and faces the electron beam generators 202. A temperature on the first side 214 of the plurality of substrates is higher than a temperature on the second side 216. For example, a temperature on the first side 214 may be between about 950 degrees Celsius and about 1200 degrees Celsius, such as about 1075 degrees Celsius. A temperature on the second side 216 may be between about 850 degrees Celsius and about 1100 degrees Celsius, such as about 975 degrees Celsius.

The difference in temperature between the first side 214 and the second side 216 may be due to the proximity of the first side 214 to the melt pool 206 which may be at a temperature of between about 2500 degrees Celsius and about 5000 degrees Celsius, such as about 3000 degrees Celsius. The difference in temperature may cause a non-uniform coating to be deposited on the plurality of substrates 212. To reduce an occurrence of a non-uniform coating, the plurality of substrates 212 are rotated along one or more axes.

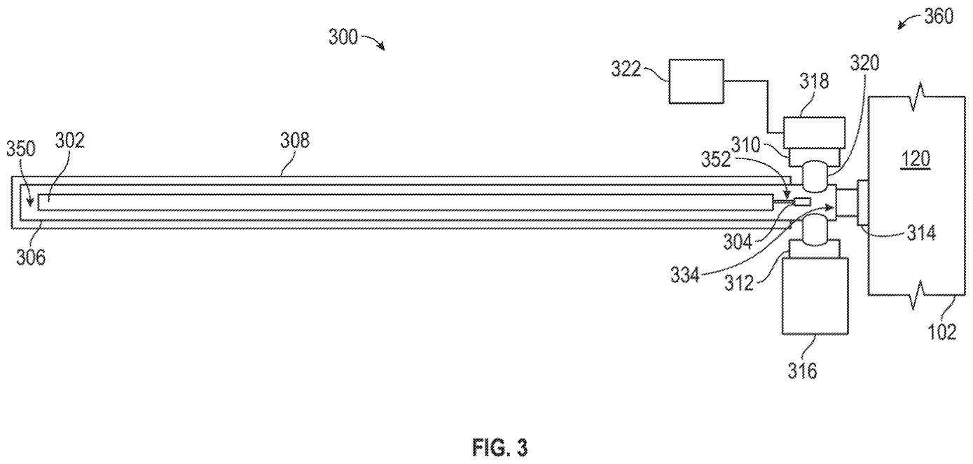

FIG. 3 is a schematic view of a probe 300, according to some embodiments. The probe 300 is coupled to the coating chamber 102. The probe includes a shaft 302, a housing 306 surrounding the shaft 302, and a flange 314 coupling the housing 306 to the coating chamber 102. The shaft 302 extends along an interior of the housing 306 from a first end 350 to a second end 352 opposite the first end 350. The second end 352 of the shaft 302 is adjacent to the coating chamber 102. In one embodiment, which can be combined with one or more embodiments discussed above, the housing 306 is cylindrical.

A test structure 304 is disposed at the second end 352 of the shaft 302. In some embodiments, which can be combined with one or more embodiments discussed above, the test structure 304 is cylindrical. In other embodiments, which can be combined with one or more embodiments discussed above, the test structure 304 may be another geometric shape. In some embodiments, which can be combined with one or more embodiments discussed above, the test structure 304 is fabricated from the same material as the substrates being processed, such as the substrates 132, 135, and 212 discussed with respect to FIGS. 1B and 2 above.

The test structure 304 may be fabricated such that a coating deposited on the test structure 304 may be substantially identical to a coating deposited on a substrate to be processed. For example, the test structure 304 may be fabricated to include one or more features of the substrates to be processed such as thin walls, cavities, recesses, holes, channels, grooves, or other features.

In some embodiments, which can be combined with one or more embodiments discussed above, one or more sensors (not shown) may be embedded in the test structure 304. The one or more sensors in the test structure 304 may measure and monitor a temperature, a coating thickness or a rate of a coating being deposited on the test structure 304. For example, a thermocouple or quartz crystal may be embedded in the test structure 304.

An actuator (not shown) is coupled to the shaft 302. The shaft 302 is moved along the housing 306 such that the shaft extends into the process volume 120 of the coating chamber 102. That is, the actuator enables the test structure 304 to be positioned in the vapor plume 210 during processing. Thus, during processing, the vaporized coating material is deposited on the test structure 304. A controller 322 may be coupled to the actuator to control movement of the probe 300.

After a period of time being positioned in the plume 210, the test structure 304 is retracted through the flange 314 into the housing 306. The test structure 304 is positioned in a measurement system 360. The measurement system 360 includes a first laser source 318, a second laser source 316, and the controller 322. The first laser source 318 and the second laser source 316 are disposed on opposite sides of the probe 300 and are aligned with a first window 310 and a second window 312. The first laser source is adjacent to the first window 310 and the second laser source 316 is adjacent to the second window 312.

Once the test structure 304 is aligned, the controller 322 initiates the first and second laser sources 318, 316 to measure a thickness of the coating deposited on the test structure 304. The thickness of the coating on the test structure is measured by determining a difference between a first distance between the laser source 318, 316 and a surface of the test structure 304 prior to coating and a second distance between the laser source 318, 316 and a surface of the coating on the test structure 304 during processing. The thickness of the coating on the test structure 304 may be calculated by the controller 322 or the measurements may be provided to a central processing unit (not shown) to perform the calculation.

If the measured thickness of the coating satisfies the target coating thickness, an endpoint of the coating process has been satisfied and the coating process is completed. However, if the measured thickness of the coating does not satisfy the target coating thickness, the test structure 304 is re-extended into the coating chamber so that an additional thickness of the coating can be deposited thereon. That is, the coating process and thickness measurement is repeated until the coating thickness satisfies the target coating thickness.

In one embodiment, which can be combined with one or more embodiments discussed above, a cooling jacket 308 is adjacent to an outer diameter of the housing 306. A cooling fluid, such as water, may flow through the cooling jacket 308 to reduce a temperature of the housing 306 and shaft 302 therein. The cooling jacket 308 prevents overheating of the housing 306 and the shaft 302 which may result in damage to one or more components of the measurement system 360.

The probe 300 enables progress of the coating process to be determined without ending the coating process. Thus, the probe 300 substantially reduces an occurrence of the coating process being terminated prior to a coating of a sufficient thickness being deposited on the substrates being processed. One or more additional sensors may be used in combination with the probe 300 and the measurement system 360. For example, one or more of the pyrometer 218 and the infrared imaging device 222, discussed with respect to FIG. 2, may be utilized. A thickness measurement of the coating deposited on the test structure 304 is substantially similar to a thickness of the coating deposited on the one or more substrates being processed, for example, the substrates 132, 135, and 212 discussed above.

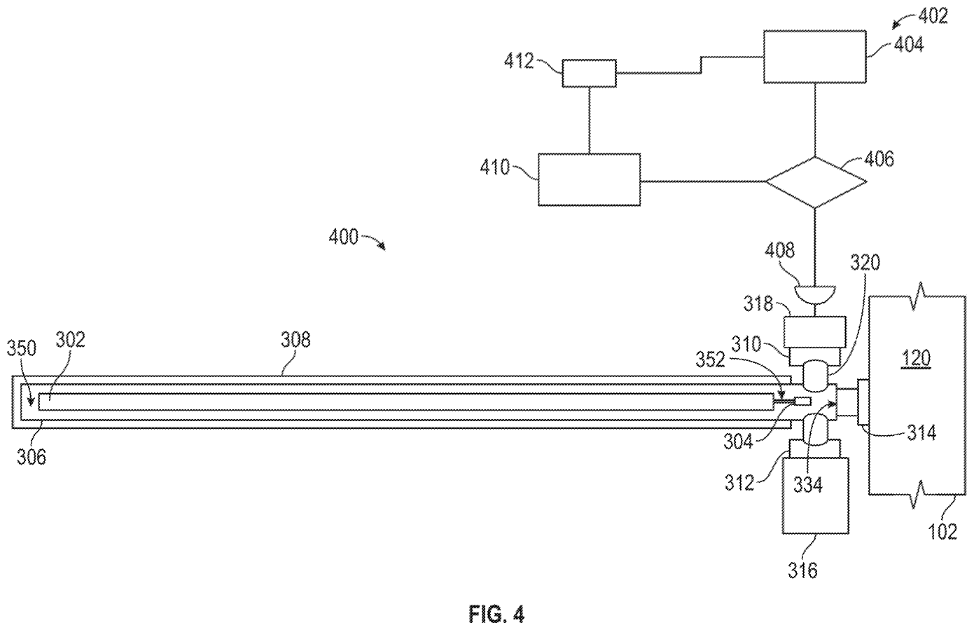

FIG. 4 is a schematic view of an alternative probe 400, according to some embodiments. The alternative probe 400 is similar to the probe discussed with respect to FIG. 3 except for the aspects discussed below.

A measurement system 402 includes a first laser source 404, a dichroic mirror 406, a microscope objective 408, and a Raman spectrometer 410. A controller 412 is coupled to and controls an output of the first laser source 404. The controller is also coupled to the Raman spectrometer 410 to control measurements performed by the Raman spectrometer 410.

In operation, the test structure 304 is retracted from the process volume 120 and aligned between the first window 310 and the second window 312. Laser energy (i.e., electromagnetic radiation) is output by the first laser source 404 and illuminates a surface of the test structure 304, including any coating deposited thereon. The microscope objective 408 focuses the laser energy to a specific portion of the surface of the test structure 304.

Some of the laser energy is reflected off the surface of the test structure 304 (or the coating disposed thereon) back to the dichroic mirror 406. The dichroic mirror 406 redirects the reflected energy to the Raman spectrometer 410. The Raman spectrometer 410 measures a structure and a composition of the coating disposed on the test structure 304.

The measurements from the Raman spectrometer 410 are used to determine if the coating deposited on the test structure (and thus the coating deposited on the substrates 132, 135, and 212) satisfies a target structure and a target composition. If the target structure and composition and not satisfied, the controller 412 or a CPU coupled thereto may determine whether a thickness of the coating should be increased or the coating on the substrates should be removed and a new coating applied thereon.

One or more other sensors may be used in combination with the probe 300 and the measurement system 402. For example, one or more of the pyrometer 218 and the infrared imaging device 222, discussed with respect to FIG. 2, and the measurement system 360 discussed with respect to FIG. 3 may be utilized. Advantageously, the measurement system 402 enables monitoring of the structure and composition of the coating deposited on the substrates, such as the substrates 132, 135 and 212 discussed above.

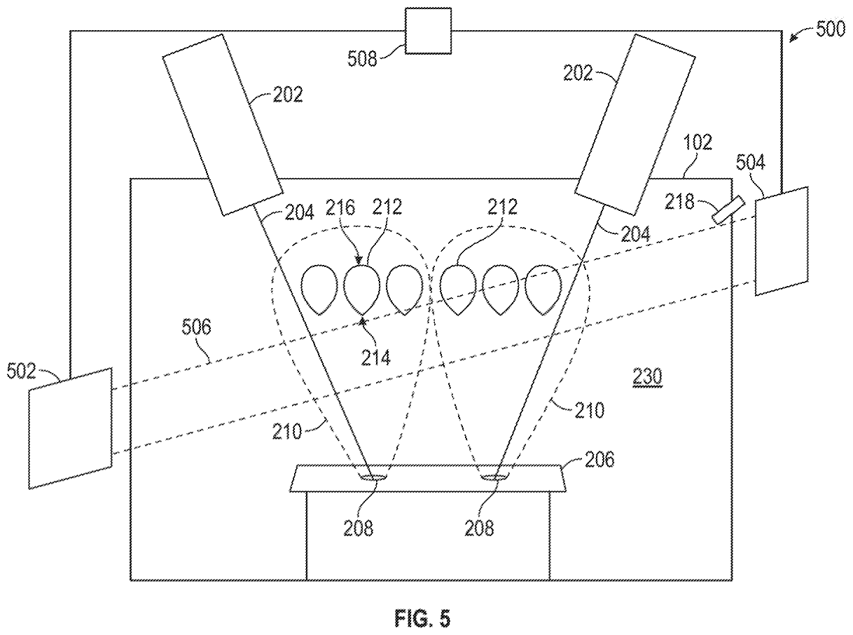

FIG. 5 is a schematic view of a measurement system 500, according to some embodiments. The measurement system 500 is similar to the measurement system 360, except that the measurement system 500 measures a thickness of a coating deposited on the one or more substrates 212 to be processed, rather than a thickness of the coating deposited on the test structure 304.

The measurement system 500 includes a first laser source 502 and a second laser source 504 disposed on opposite sides of the coating chamber 102. The first laser source 502 and the second laser source 504 are aligned with at least one of the one or more substrates 212 to be processed. Each of the first laser source 502 and the second laser source 504 are coupled to a controller 508.

In one embodiment, which can be combined with one or more embodiments discussed above, the controller 508 may be a separate controller from the controller 220 discussed with respect to FIG. 2. The controller 508 may also represent the controller 220. That is, although not shown in FIG. 5, the controller 508 may be coupled to the electron beam generators 202, the pyrometer 218, and the infrared imaging device 222.

In operation, the measurement system 500 may be used to perform a measurement operation to determine a thickness of a coating deposited on the one or more substrates 212. The controller 508 determines at what time the measurement system 500 performs the measurement operation. For example, the measurement system 500 may perform the measurement operation at a specific time interval during the coating process. The measurement system 500 may also perform the measurement operation continuously during the coating operation.

The measurement operation performed by the measurement system 500 includes determining a first distance between the first laser source 502 or the second laser source 504 and at least one of the one or more substrates 212 prior to the coating operation. Once the coating operation has begun, the measurement system 500 determines a second distance between the first laser source 502 or the second laser source 504 and at least one of the one or more substrates 212. The coating thickness is the difference between the second distance and the first distance.

Advantageously, the measurement system 500 provides a real-time thickness measurement of the coating deposited on the one or more substrates 212. Thus, the coating process may be performed with minimal interruptions or downtime. Accordingly, the measurement system 500 improves efficiency of the coating process. The measurement system 500 may be used in combination with one or more other sensors such as one or more of the pyrometer 218 and the infrared imaging device 222 discussed with respect to FIG. 2, the measurement system 360 discussed with respect to FIG. 3, and the measurement system 402 discussed with respect to FIG. 4.

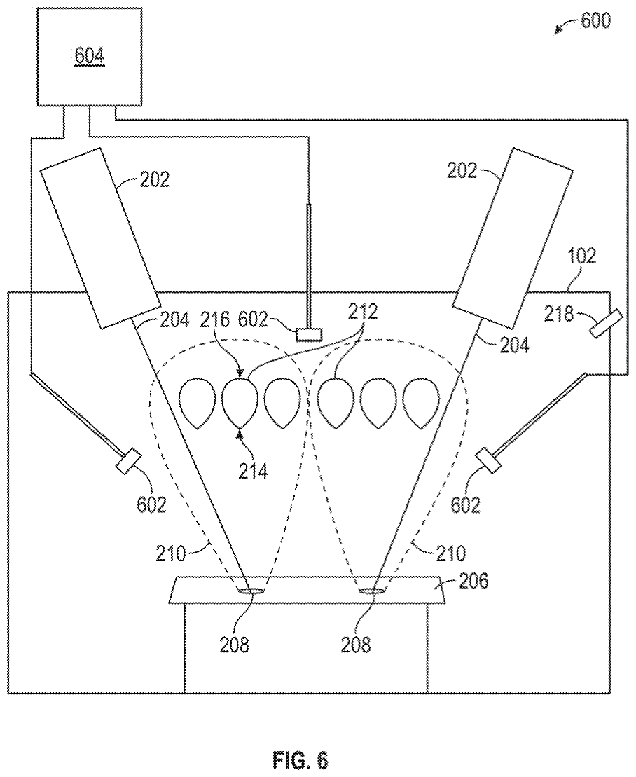

FIG. 6 is a schematic view of a coating chamber 600, according to some embodiments. The coating chamber 600 is similar to the coating chambers 102 and 200 discussed above. The coating chamber 600 includes one or more quartz crystal monitors 602 disposed therein. That is, the one or more quartz crystal monitors 602 are disposed in or adjacent to the plumes 210.

The one or more quartz crystal monitors 602 include an oscillating quartz crystal. As the coating is deposited on the crystal, the oscillation rate (e.g., frequency) of the crystal changes. The change in oscillation rate is used to determine a deposition rate of the coating. The deposition rate is used to determine a thickness of the coating deposited on the substrates 212. The deposition rate can also be used to determine a distribution and a temperature of the vapor plume 210.

A controller 604 is coupled to each of the one or more quartz crystal monitors 602. The controller receives a signal from the one or more quartz crystal monitors 602 and determines the deposition rate of the coating on each of the one or more quartz crystal monitors 602. The controller 604 may correspond to one or more of the controllers 220, 322, 412, and 508 discussed above. In one embodiment, which can be combined with one or more embodiments discussed above, the controller 604 may be separate from and coupled to one or more of the controllers 220, 322, 412, and 508 discussed above.

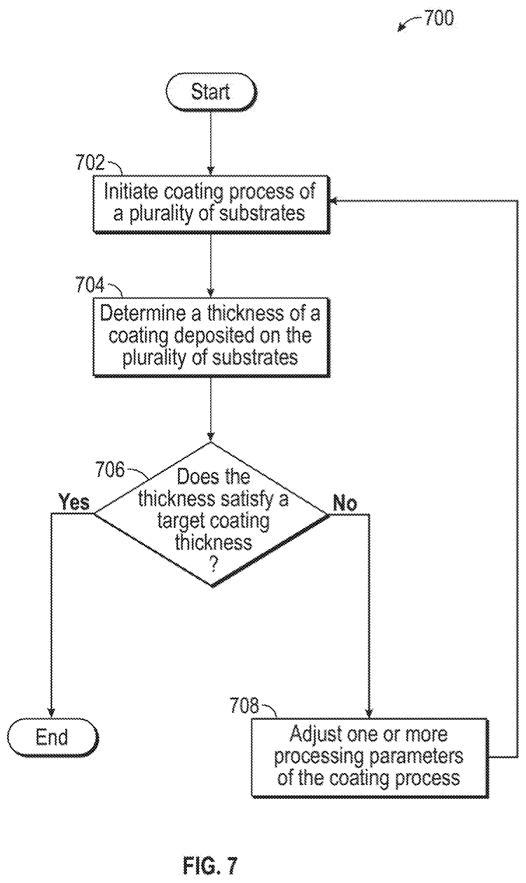

FIG. 7 is a flow chart depicting operations 700 for monitoring a thickness of a coating deposited on a substrate, according to some embodiments. The operations 700 begin at operation where a coating process is initiated on a plurality of substrates disposed in a coating chamber. The coating chamber may correspond to the coating chambers 102 and 200 discussed above. The plurality of substrates may correspond to the substrates 132, 135, and 212 discussed above.

At operation 704, a thickness of a coating deposited on the plurality of substrates. The thickness of the coating may be determined using one or more sensors or measurement systems, such as the pyrometer 218, the infrared imaging device 222, the measurement system 360, the measurement system 402, or the measurement system 500 discussed above.

At operation 706, it is determined if the thickness of the coating satisfies a target coating thickness. One or more controllers, such as the controllers 220, 322, 412, 508, and 604, may determine whether the target coating thickness is satisfied based on data from one or more of the sensors and measurement systems. If the coating thickness does not satisfy the target coating thickness, operations 702 through 706 are repeated until the target coating thickness is satisfied.

Upon determining the target coating thickness is satisfied, an endpoint of the coating process is detected and the coating process for the plurality of substrates is completed. The operations 700 may be repeated for an additional plurality of substrates.

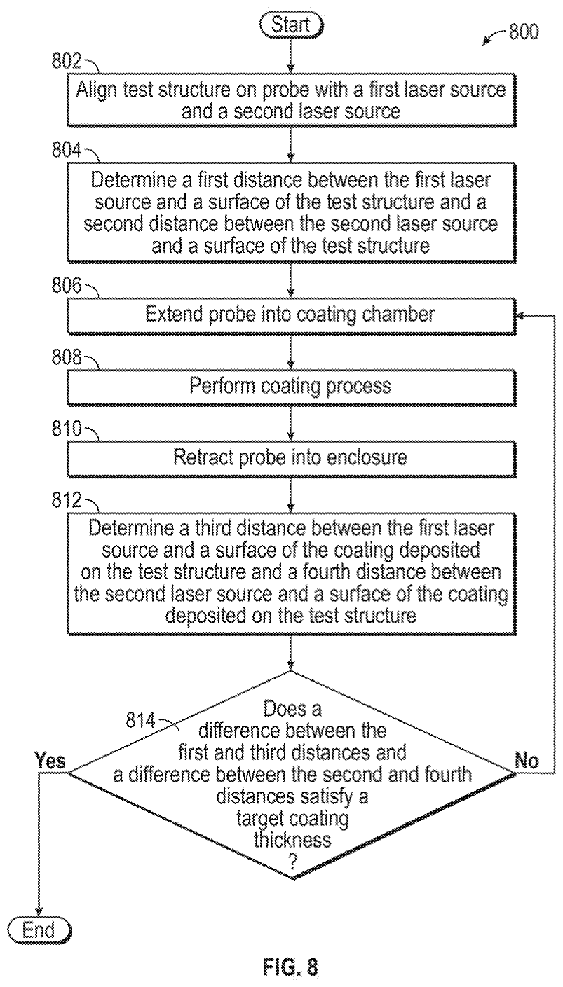

FIG. 8 is a flow chart depicting operations 800 for monitoring a thickness of a coating deposited on a substrate, according to some embodiments. The operations 800 begin at operation 802 where a test structure on a probe, such as the probe 300 and the test structure 304 discussed with respect to FIGS. 3 and 4, is aligned with a first laser source and a second laser source within an enclosure, such as the first laser source 318 and the second laser source 316, respectively, discussed with respect to FIG. 3.

At operation 804, a first distance between the first laser source and a surface of the test structure is determined and a second distance between the second laser source and another surface of the test structure are determined.

At operation 806, the probe and test structure are extended into a coating chamber. The test structure is extended into the coating chamber such that the test structure is positioned within a vapor plume adjacent to one or more substrates to be processed, such as the vapor plumes 210 and the substrates 132, 153, and 212 discussed above.

At operation 808, a coating process is performed on the one or more substrates. A coating deposited on the one or more substrates during the coating process is also deposited on the test structure.

At operation 810, the probe and test structure are retracted into the enclosure. The test structure is aligned between the first laser source and the second laser source.

At operation 812, a third distance is between the first laser source and a surface of the coating deposited on the test structure is determined and a fourth distance between the second laser source and another surface of the coating deposited on the test structure are determined.

At operation 814, a first difference between the first distance and the third distance is determined. A second difference between the second distance and the fourth distance is determined. The first difference and the second difference are compared to a target coating thickness. If the first difference or the second difference does not satisfy the target coating thickness, operations 806 through 814 are repeated.

Upon determining the first difference and the second difference satisfy the target coating thickness, an endpoint of the coating process is achieved and the coating process is completed and the substrates are removed from the coating chamber.

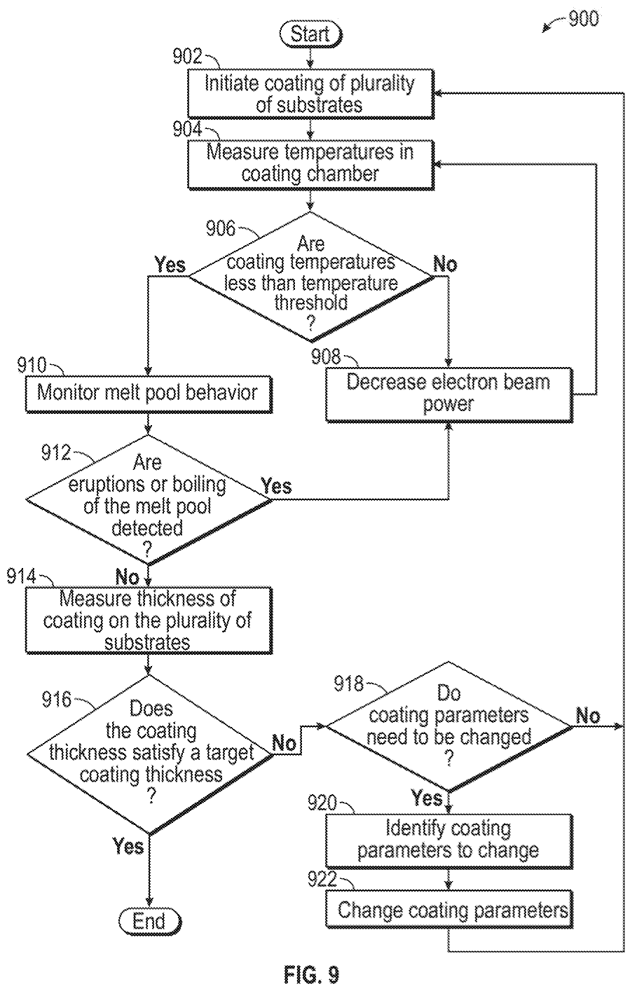

FIG. 9 is a flow chart depicting operations 900 for monitoring various parameters of a coating procedure performed in a coating chamber, according to some embodiments. The operations 900 begin at operation 902 where a coating process is initiated to deposit a coating on a plurality of substrates.

At operation 904, one or more sensors in the coating chamber measure a temperature in the coating chamber. For example, one or more pyrometers, such as the pyrometers 218 discussed with respect to FIG. 2, or a probe, such as the probe 300 discussed with respect to FIG. 3, may be used to measure a temperature of the plurality of substrates, a chamber liner, a vapor plume, a substrate holder, or other components of the coating chamber. The measured temperature is transmitted to a controller coupled to the sensor or probe. Alternatively or in addition, the measured temperature may also be transmitted to a central processing unit coupled to the sensor or probe.

At operation 906, the controller and/or central processing unit determines whether the measured temperature satisfies (e.g., is less than) a temperature threshold. If the measured temperature fails to satisfy the temperature threshold, the controller and/or central processing unit decreases a power of the electron beam generator at operation 908, such as the electron beam generators 202 discussed with respect to FIGS. 2, 5, and 6. Once the power of the electron beam generator is decreased, operations 904 through 906 are repeated until the measured temperature satisfies the temperature threshold.

Once the measured temperature satisfies the temperature threshold, a melt pool in the coating chamber is monitored at operation 910. The melt pool may be monitored using an infrared imaging device, such as the infrared imaging device 222 discussed with respect to FIG. 2. A signal is transmitted from the infrared imaging device to the controller and/or central processing unit.

At operation 912, the controller and/or central processing unit determines if contents of the melt pool is boiling or erupting. If the contents of the melt pool are boiling or erupting, the controller and/or central processing unit decreases a power of the electron beam generator at operation 908. Decreasing the power of the electron beam generator reduces a temperature of the contents of the melt pool. Once the power of the electron beam generator is decreased, operations 904 through 912 are repeated.

Upon determining that the contents of the melt pool are not boiling or erupting, a thickness of a coating deposited on the plurality of substrates is measured at operation 914. The thickness of the coating may be measured using a probe and/or a measurement system, such as the probe 300 discussed with respect to FIGS. 3 and 4, and the measurement systems 500 and/or 600, discussed with respect to FIGS. 5 and 6. A measurement is transmitted to the controller and/or the central processing unit.

At operation 916, the controller and/or central processing unit determines if the measured thickness satisfies a target coating thickness.

If the measured thickness does not satisfy the target coating thickness, the controller and/or central processing unit determines if one or more coating parameters needs to be changed at operation 918. For example, the controller and/or central processing unit may determine that one or more of a temperature, a power of the electron beam generator, or a rotation speed of the one or more substrates should be changed.

If the coating parameters do not need to be changed, the operations 902 through 916 are repeated so that an additional coating is deposited on the plurality of substrates. If one or more coating parameters do need to be changed, the controller and/or central processing unit identify which parameter(s) needs to be changed at operation 920.

At operation 922, the controller and/or central processing unit change the identified coating parameter(s). Once the coating parameter(s) is changed, operations 902 through 916 are repeated until the measured coating thickness satisfies the target coating thickness. Upon determining that the measured coating thickness satisfies the target coating thickness at operation 916, an endpoint of the coating process is attained and the coating process is completed.

The operations 900 may be repeated for an additional coating material. For example, a different coating material may be added or substituted to the melt pool to deposit an additional coating to the plurality of substrates. The endpoint of the coating process of the different coating material may be after a different length of time than the coating process performed with the original coating material.

What is claimed is:

1. A method for detecting an endpoint of a coating process, the method comprising:
measuring a temperature of a plurality of substrates being processed;
comparing the measured temperature to a temperature threshold;
upon determining that the measured temperature does not satisfy the temperature threshold, adjusting a parameter of the coating process;
upon determining that the measured temperature satisfies the temperature threshold, measuring a thickness of a coating deposited on the plurality of substrates;
comparing the measured coating thickness to a target coating thickness; and
upon determining that the measured coating thickness does not satisfy the target coating thickness, depositing an additional thickness of the coating on the plurality of substrates.

2. The method of claim 1, further comprising:
upon determining that the measured coating thickness satisfies the target coating thickness, identifying an endpoint of the coating process.

3. The method of claim 1, wherein the parameter of the coating process includes at least one of one or more axes of rotation of the plurality of substrates, a speed of rotation of the plurality of substrates, and a power provided to one or more electron beam generators.

4. The method of claim 1, further comprising:
rotating each substrate of the plurality of substrates along more than one axis during the coating process.

5. The method of claim 1, wherein the thickness of the coating deposited on the plurality of substrates is determined by the coating on a test structure.

6. The method of claim 1, wherein the thickness of the coating deposited on the plurality of substrates is determined by depositing the coating on one or more quartz crystal monitors.

7. The method of claim 1, wherein the temperature of the plurality of substrates is measured by one or more pyrometers.

8. A method of measuring a coating thickness, comprising:
aligning a test structure disposed on a probe between a first window and a second window;
measuring a first distance between a first laser source through the first window and a first surface of the test structure;
measuring a second distance between a second laser source through the second window and a second surface of the test structure;
extending the probe into a process chamber in which a coating is applied to a plurality of substrates and the test structure;
retracting the probe from the process chamber to align the test structure between the first window and the second window;
measuring a third distance between the first laser source and a surface of the coating deposited on the first surface of the test structure;
measuring a fourth distance between the second laser source and a surface of the coating deposited on the second surface of the test structure;
determining a first difference between the first distance and the third distance;
determining a second difference between the second distance and the fourth distance;
determining a thickness of the coating based on the first difference and the second difference;
comparing the thickness of the coating to a target coating thickness; and
upon determining the thickness of the coating satisfies the target coating thickness, identifying an endpoint of a coating process performed on the plurality of substrates.

9. The method of claim 8, further comprising:
maintaining a temperature of the probe by flowing a cooling fluid through a cooling jacket surrounding the probe.

10. The method of claim 9, further comprising:
determining a thickness of the coating deposited on the plurality of substrates via a third laser source substantially parallel to the probe.

11. The method of claim 10, further comprising:
determining an first oscillation rate of a quartz crystal monitor prior to the extending the probe into a process chamber; and
determining a second oscillation rate of the quartz crystal monitor after the retracting the probe from the process chamber;
determining a third difference between the first oscillation rate and the second oscillation rate; and
determining a thickness of the coating based on the third difference.

12. The method of claim 8, further comprising:
measuring a temperature of the plurality of substrates in the process chamber via one or more pyrometers disposed therein.

13. The method of claim 8, wherein the coating is continuously deposited on the plurality of substrates during the retracting, measuring the third distance and the fourth distance, determining, and comparing operations.

14. A process chamber, comprising:
a body defining a process volume therein;
a melt pool disposed in the process volume having one or more ingots disposed therein;
one or more electron beam generators disposed opposite the melt pool;
a plurality of substrates disposed in the process volume between the one or more electron beam generators and the melt pool;
a probe assembly, comprising:
an enclosure having a first window and a second window opposite the first window, the first window and the second window adjacent to the body;
a shaft disposed in the enclosure; and
a test structure disposed on the shaft; and
a controller configured to perform the following operations:
aligning the test structure in the enclosure between the first window and the second window;
rotating each substrate of the plurality of substrates about more than one axis;
vaporizing the one or more ingots to generate a vapor plume surrounding the plurality of substrates by controlling a power provided to the one or more electron beam generators;
extending the test structure into the vapor plume;
retracting the test structure into the enclosure;
aligning the test structure between the first window and the second window;
determining a thickness of a coating deposited on the test structure; and
upon determining that the thickness of the coating satisfies a target coating thickness, identifying an endpoint of a coating process for the plurality of substrates.

15. The process chamber of claim 14, further comprising:
an actuator coupled to the shaft, wherein the controller is coupled to the actuator.

16. The process chamber of claim 14, further comprising:
one or more pyrometers disposed adjacent to the body.

17. The process chamber of claim 16, wherein the probe assembly further comprises:
a dichroic mirror;
a microscope objective disposed between the dichroic mirror and the first window; and
a Raman spectrometer aligned with the dichroic mirror, the Raman spectrometer coupled to the controller.

18. The process chamber of claim 17, further comprising:
an infrared imaging device for monitoring a behavior of contents of the melt pool.

19. The process chamber of claim 18, wherein the operations of the controller further include:
determining a composition of the coating using the Raman spectrometer; and
upon determining the composition fails to satisfy a target composition, adjusting one or more parameters of the coating process.

20. The process chamber of claim 19, wherein the one or more parameters includes at least one of one or more axes of rotation of the plurality of substrates, a speed of rotation of the plurality of substrates, a composition of the one or more ingots, and a power provided to the one or more electron beam generators.
